(19) United States
(12) Patent Application Publication
(10) Pub. No.: US 2006/0134531 A1
(43) Pub. Date: Jun. 22, 2006

(54) Mask for electromagnetic radiation and method of fabricating the same

(76) Inventors: I-Hun Song, Seongnam-si (KR); Won-Il Ryu, Seoul (KR); Suk-Pil Kim, Yongin-si (KR); Hoon Kim, Siheung-si (KR); Seung-Hyuk Chang, Seongnam-si (KR); Won-Joo Kim, Suwon-si (KR); Young-Soo Park, Suwon-si (KR)

Correspondence Address: HARNESS, DICKEY & PIERCE, P.L.C., P.O. BOX 8910, RESTON, VA, 20195, US

(21) Appl. No.: 11/274,474

(22) Filed: Nov. 16, 2005

(30) Foreign Application Priority Data
Nov. 16, 2004 (KR) 10-2004-0093573
Jul. 22, 2005 (KR) 10-2005-0066990

(51) Int. Cl. G03C 5/00; G21K 5/00; G03F 1/00

(52) U.S. Cl. 430/5; 378/35; 430/322; 430/323; 430/324

(57) ABSTRACT

A mask for lithography and a method of manufacturing the same. The mask may include a substrate, a reflection layer formed of a material capable of reflecting electromagnetic rays on the substrate and an absorption pattern formed in a desired pattern such that absorbing regions with respect to electromagnetic rays and windows through which electromagnetic rays pass are formed, wherein the absorption pattern includes at least one side surface that is adjacent to the window and is inclined with respect to the reflection layer. The method may include forming a reflection layer which is formed of a material capable of reflecting electromagnetic rays on a substrate, forming an absorption layer which is formed of a material capable of absorbing electromagnetic rays on the refection layer, and patterning the absorption layer to form an absorption pattern with at least one side surface adjacent to a window that has an inclined side surface with respect to the reflection layer.

This application claims the benefit of Korean Patent Application Nos. 10-2004-0093573, filed on Nov. 16, 2004, and 10-2005-0066990, filed on Jul. 22, 2005 in the Korean Intellectual Property Office, the disclosures of which are incorporated herein in their entirety by reference.

### BACKGROUND OF THE INVENTION

1. Field of the Invention

Example embodiments of the present invention relate to a mask for electromagnetic radiation and a method of fabricating the same, and more particularly, to a mask for electromagnetic radiation that is suitable for a high resolution photolithography technique for a semiconductor manufacturing process using electromagnetic rays and a method of fabricating the same.

2. Description of the Related Art

In photolithography processes for semiconductor manufacturing processes, a technique using an exposure wavelength of an extreme ultra violet (EUV) region that may be the same or similar to a “soft X ray” has been studied as an exposure technique capable of realizing a pattern size of 100 nm or less.

Because most materials absorb light in the EUV regions, an exposure technique using EUV may require a mask for EUV lithography (EUVL). A general mask for EUV may be formed such that a pattern formed of an absorbing substance that can absorb EUV rays is formed on a mirror (for example, a reflective mirror) with high reflectivity in the EUV region. Therefore, there is an absorption region where the surface of the mirror is covered by an absorption pattern and a reflection region where the surface of the mirror is not covered by the absorption pattern and thus exposed.

FIG. 1 is a sectional view illustrating a conventional mask for EUVL 1.

Referring to FIG. 1, a conventional mask for EUVL 1 may include a substrate 2 formed of silicon, glass, or other suitable material, a reflection layer 3 formed on the substrate 2, and an absorption pattern 4 formed on the reflection layer 3. Reference numeral 5 denotes a silicon wafer.

The reflection layer 3 may have a multi-layer structure formed by alternatively depositing a heterolayer, for example, a Mo/Si layer or a Be/Si layer. The absorption pattern 4 may be formed of TaN, which absorbs EUV rays and has a given pattern, thus forming an absorption region with respect to EUV rays.

When the mask for EUVL 1 is exposed to EUV rays, the dimensions of the absorption pattern 4 are different from the respective dimensions of a pattern formed in the silicon wafer 5, as described by Equations 1 and 2 below. Equation 1 represents the relationship between a designed space critical dimension (CD), which is an interval between the patterns of the absorption pattern 4, and a printed space CD, which is an interval between patterns formed in the silicon wafer 5 corresponding to the absorption pattern 4. Equation 2 represents the relationship between the designed line CD, which is a length of one pattern of the absorption pattern 4, and the printed line CD, which is a length of the corresponding pattern formed in the silicon wafer 5 corresponding to each unit of the absorption pattern 4:
Printed Space CD=Designed Space CD−2d×tan θ×M (1)
Printed Line CD=Designed Line CD+2d×tan θ×M (2)
where d is a thickness of the absorption pattern 4, θ is the angle of incidence of EUV rays with respect to a side surface of the absorption pattern 4, and M is a reduction factor.

According to a conventional photolithography process for a semiconductor manufacturing process, the absorption pattern 4 has vertical side surfaces, and thus, θ is a given angle, and thus, the term of 2d×tan θ×M in Equations 1 and 2 has a given value. Accordingly, the designed space CD may be different from the printed space CD and the designed line CD may be different from the printed line CD. Due to these differences, a shape designed in the absorption pattern 4 cannot be realized precisely in the silicon wafer 5.

### SUMMARY OF THE INVENTION

Example embodiments of the present invention provide a mask for electromagnetic radiation and a method of manufacturing the same.

Example embodiments of the present invention provide a mask for EUVL that can more precisely realize a shape designed in an absorption pattern and a method of manufacturing the same.

Example embodiments of the present invention provide a mask that can more precisely realize a shape designed in an absorption pattern and a method of manufacturing the same.

According to an example embodiment of the present invention, there is provided a mask for lithography including a substrate, a reflection layer formed of a material capable of reflecting rays, for example, extreme ultra violet (EUV) rays on the substrate, and an absorption pattern having an absorption region with respect to rays, for example, EUV rays and a window through which rays, for example, EUV rays pass, wherein the absorption pattern includes at least one side surface that is adjacent to the window and is inclined with respect to the reflection layer.

In an example embodiment, the absorption pattern may further include at least one side surface that is perpendicular to the reflection layer such that the absorption pattern has at least one inclined side surface and at least one vertical side surface.

In an example embodiment, the absorption pattern may have a first absorption pattern having at least one inclined side surface and a second absorption pattern having at least one vertical side surface.

In an example embodiment, at least two side surfaces of an absorption pattern may be inclined with respect to the reflection layer.

In an example embodiment, the cross-section of an absorption pattern may be trapezoid-shaped.

In an example embodiment, an absorption pattern may be formed in a direction perpendicular to an incident plane of rays, for example, EUV rays, and another absorption pattern may be formed in a direction parallel to the incident plane of rays, for example, EUV rays.

In an example embodiment, the inclined side surface(s) of an absorption pattern may have an angle of inclination equal to the angle of incidence of rays, for example, EUV rays, incident on the reflection layer.

In an example embodiment, two or more side surfaces of an absorption pattern may be inclined side surfaces, inclined with respect to the reflection layer.

In an example embodiment, the cross-section of an absorption pattern having an inclined side surface may be trapezoid-shaped.

In an example embodiment, an absorption pattern may be formed of a metal-containing material.

In an example embodiment, an absorption pattern may be formed of an element selected from the group consisting of TaN, Ta, Cr, TiN, Ti, Al—Cu, NiSi, TaSiN, and Al.

In an example embodiment, a reflection layer may be composed of alternatively deposited first material layers and second material layers.

In an example embodiment, a first material layer may be formed of an element selected from the group consisting of Mo, Sc, Ti, V, Cr, Fe, Ni, Co, Zr, Nb, Tc, Ru, Rh, Hf, Ta, W, Re, Os, Ir, Pt, Cu, Pd, Ag, and Au.

In an example embodiment, a second material layer may be formed of a material selected from the group consisting of silicon, silicon carbonate, silicon nitride, silicon oxide, boron nitride, beryllium nitride, beryllium oxide, aluminum nitride, and aluminum oxide.

In an example embodiment, the rays may be EUVL radiation, soft X-ray, or other electromagnetic radiation.

According to another example embodiment of the present invention, there is provided a method of manufacturing a mask, the method including forming a reflection layer formed of a material capable of reflecting rays, for example, EUV rays, on a substrate, forming an absorption layer formed of a material capable of absorbing the rays on the refection layer, and patterning the absorption layer to form an absorption pattern with at least one side surface adjacent to a window that include at least one inclined side surface with respect to the reflection layer.

In an example embodiment, forming the absorbing pattern in the absorbing layer may include forming a resist layer on the absorption layer, patterning the resist layer to form a resist pattern, and patterning the absorption layer using the resist pattern as a mask to form the absorption pattern having at least one inclined side surface.

In an example embodiment, forming the resist pattern in the resist layer may include forming a resist pattern having at least one side surface inclined equal to the angle of incidence of rays and forming the inclined absorption pattern in the absorption layer may include forming an absorption pattern having at least one side surface inclined equal to an angle of inclination of at least one side surface of the resist pattern.

In an example embodiment, two or more side surfaces of the resist pattern may be formed to have an angle of inclination equal to the angle of incidence of the rays, for example, EUV rays.

In an example embodiment, two or more side surfaces of the absorption pattern may be formed to be inclined equal to the angle of inclination of a side surface of the resist pattern.

In an example embodiment, the cross-section of a resist pattern is trapezoid-shaped.

In an example embodiment, forming an absorption pattern may include patterning an absorption layer further to have at least one side surface vertical to a reflection layer to form an absorption layer having mixed side surfaces, including at least one inclined side surface and at least one vertical side surface.

In an example embodiment, an absorption pattern may include a first absorption pattern having at least one inclined side surface and a second absorption pattern having at least one vertical side surface.

In an example embodiment, two or more side surfaces of an absorption pattern may be inclined with respect to a reflection layer.

In an example embodiment, the cross-section of the first absorption pattern may be trapezoid-shaped.

In an example embodiment, an absorption pattern may be formed in a direction perpendicular to an incident plane of rays, for example, EUV rays, and another absorption pattern may be formed in a direction parallel to the incident plane of rays, for example, EUV rays.

In an example embodiment, forming the absorption pattern in the absorption layer may include forming a resist layer on the absorption layer, forming a resist pattern having at least one side surface with an angle of inclination equal to the angle of inclination of at least one side surface of the absorption pattern to be formed, on the resist layer, and forming the absorption pattern in the absorption layer using the resist pattern as a mask such that an angle of inclination of at least one side surface of the absorption pattern with respect to the reflection layer is equal to the angle of inclination of at least one side surface of the resist pattern with respect to the reflection layer.

In an example embodiment, forming the resist pattern may include patterning the resist layer in at least two stages including forming a first resist pattern having at least one side surface with an angle of inclination equal to an angle of incidence of the rays, for example, EUV rays to be used to form the absorption pattern having at least one inclined side surface and forming a second resist pattern having at least one side surface with an angle of inclination of 90° to be used to form the absorption pattern having at least one vertical side surface, and forming of the absorption pattern side surface using the first resist pattern and the portion of the absorption pattern having at least one vertical side surface using the second resist pattern.

In an example embodiment, two or more side surfaces of the first resist pattern may be formed to be inclined equal to the angle of incidence of rays, for example, EUV rays.

In an example embodiment, a section of the first resist pattern may have a trapezoidal shape.

In an example embodiment, the absorption pattern may be formed such that at least one side surface of the absorption pattern adjacent to a window has an angle of inclination equal to the angle of incidence of rays, for example, EUV rays.

In an example embodiment, the absorption pattern may be formed to have a trapezoid-shaped cross section.

### BRIEF DESCRIPTION OF THE DRAWINGS

The present invention will become more apparent by describing in detail example embodiments thereof with reference to the attached drawings in which:

FIG. 1 is a sectional view of a conventional mask for extreme ultra violet lithography (EUVL);

FIG. 2 is a sectional view of a mask for EUVL according to an example embodiment of the present invention;

FIGS. 3A through 3E are sectional views illustrating a method of manufacturing a mask for EUVL according to an example embodiment of the present invention;

FIG. 4 is a perspective view of a mask for EUVL according to another example embodiment of the present invention, wherein an absorption pattern is partially illustrated;

FIG. 5A is a schematic sectional view of an example profile of the first absorption pattern of FIG. 4;

FIG. 5B is a schematic sectional view of and example profile of the second absorption pattern of FIG. 4;

FIGS. 6 through 8B are sectional views illustrating a method of manufacturing a mask for EUVL according to another example embodiment of the present invention;

FIG. 9 is a plan view of an absorption pattern including the first and second absorption patterns of FIG. 4 according to an example embodiment of the present invention;

FIG. 10 is an image of a section of an absorption pattern that has inclined side surfaces formed under desired conditions according to an example embodiment of the present invention; and

FIG. 11 is an image of a section of an absorption pattern that has vertical side surfaces formed under desired conditions according to an example embodiment of the present invention.

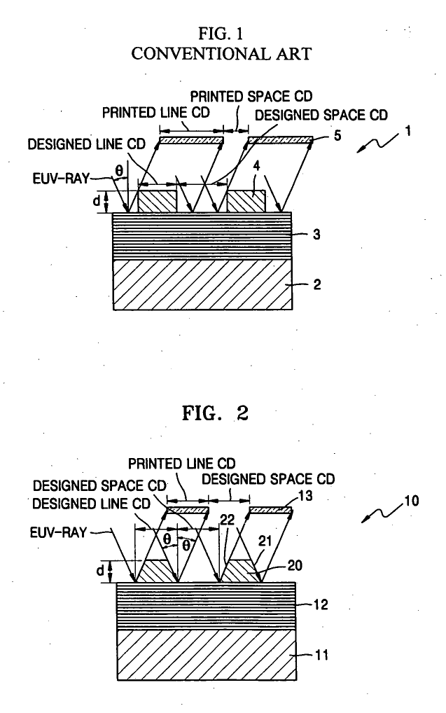

### DETAILED DESCRIPTION OF EXAMPLE EMBODIMENTS OF THE INVENTION

Masks for extreme ultra violet lithography (EUVL) and methods of manufacturing the same according to example embodiments of the present invention will now be described more fully with reference to the accompanying drawings. Like reference numerals in the drawings denote like elements. In the drawings, the thicknesses of layers and regions are exaggerated for clarity. It will also be understood that when an element, such as, layer, region or substrate, is referred to as being “on” another element, it can be directly on the other element, or intervening elements may also be present. In addition, because the angle of incidence of extreme ultra violet (EUV) rays with respect to a reflection layer is equal to the reflection angle of the EUV rays, both the incidence angle and the reflection angle will be referred to as an incidence angle. A window may be defined as a portion between absorption patterns through which the EUV ray passes.

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

FIG. 2 is a sectional view of a mask for EUVL according to an example embodiment of the present invention.

Referring to FIG. 2, the mask 10 for EUVL may include a substrate 11 formed of silicon, glass, or other suitable material, a reflection layer 12 formed on the substrate 11, and/or an absorption pattern 20 formed on the reflection layer 12. Reference numeral 13 in FIG. 2 denotes a semiconductor wafer, for example, a silicon wafer.

The reflection layer 12 may be formed of a material that can reflect EUV rays. The reflection layer 12 may be formed by alternatively depositing different material layers. For example, the reflection layer 12 may be a multilayer formed by repeatedly alternately depositing Mo and Si. The uppermost sub layer of the reflection layer 12 may be one of the Mo layers or the Si layers, for example, a Si layer because a natural oxidation layer formed on silicon has excellent stability. The thickness of each of the Mo and Si layers may be on the order of a few nm. The reflection layer 12 may include several tens of Mo layers and Si layers.

In the reflection layer 12, Mo can be replaced with Sc, Ti, V, Cr, Fe, Ni, Co, Zr, Nb, Tc, Ru, Rh, Hf, Ta, W, Re, Os, Ir, Pt, Cu, Pd, Ag, Au, or other suitable material and Si can be replaced with silicon carbonate, silicon nitride, silicon oxide, boron nitride, beryllium nitride, beryllium oxide, aluminum nitride, aluminum oxide, or other suitable material.

The absorption pattern 20 may be formed in a desired pattern such that an absorption region with respect to EUV rays is formed and windows through which the EUV rays pass are formed.

The absorption pattern 20 may be formed of a material that can absorb EUV rays, for example, a material containing a metal material. For example, the absorption pattern 20 may be formed of TaN or other suitable material, and may have a desired pattern, thus forming an absorption region with respect to EUV rays. The absorption pattern 20 may be formed of TaN, Ta, Cr, TiN, Ti, Al—Cu, NiSi, TaSiN, Al, or other suitable material.

In an example embodiment of the present invention, one or more side surfaces 21 and 22 of the absorption pattern 20 adjacent to windows may be inclined with respect to the reflection layer 12. Angles of inclination of the inclined side surfaces 21 and 22 of the absorption pattern 20 may be substantially equal to the angle of incidence of the EUV rays. In an example structure, when the mask for EUVL 10 is exposed to EUV rays, respective dimensions of the absorption pattern 20 may be substantially equal to respective dimensions of a pattern formed in the silicon 13, which will be described with reference to Equations 3 and 4 below.

Equation 3 represents the relationship between a designed space CD, which is an interval of each pattern of the absorption pattern 20, and a printed space CD, which is an interval of the corresponding pattern formed in the silicon wafer 13. Equation 4 represents the relationship between a designed line CD, which is a length of one pattern of the absorption pattern 20, and a printed line CD, which is a length of the corresponding pattern formed in the silicon water 13:
Printed Space CD=Designed Space CD (3)
Printed Line CD=Designed Line CD (4).

In an example embodiment of the present invention, Equations 3 and 4 are obtained based on the following.

In an example embodiment of the present invention, angles of inclination of the inclined side surfaces 21 and 22 of the absorption pattern 20 are almost equal to the angle of incidence of the EUV rays. Accordingly, this corresponds to θ of Equations 1 and 2 presented above in relation to the conventional mask for EUVL is almost 0°. Although in example embodiments θ may be 0°, θ may also be almost 0°, taking into consideration one or more manufacturing errors. When θ is 0°, 2d×tan θ×M of Equations 1 and 2 in relation to the conventional mask for EUVL is equal to 0.

Therefore, in example embodiments of the present invention the designed space CD may be equal to the printed space CD and/or the designed line CD may be equal to the printed line CD. Therefore, a shape designed in the absorption pattern 20 can be more precisely realized in the silicon wafer 13.

In addition, 2d×tan θ×M of Equations 1 and 2 in relation to the conventional mask for EUVL is zero, because, as is apparent from Equations 3 and 4, when the mask for EUVL 10 according to an example embodiment of the present invention is used. In an example embodiment, the space CD and/or the line CD may be independent of the thickness d of the absorption pattern 20. Therefore, the thickness of the absorption pattern 20 can be substantially reduced while attaining a desired absorbing ratio, and thus, process time and/or process error may be reduced.

In an example embodiment, two or more side surfaces of the absorption pattern 20 may be inclined with respect to the reflection layer 12 to enhance the effect described above. In an example embodiment, two or more side surfaces of the absorption pattern 20 have angles of inclination equal to the angle of incidence of the EUV rays. In an example embodiment, the cross-section of the absorption pattern 20 has a trapezoidal shape.

In an example embodiment of the present invention, the inclination of the one or more side surfaces 21 and 22 of the absorption pattern 20 may be reversed from the configuration illustrated in FIG. 2. In an example embodiment of the present invention, one or more side surfaces 21 and 22 of the absorption pattern 20 may be inclined at different angles with respect to the reflection layer 12.

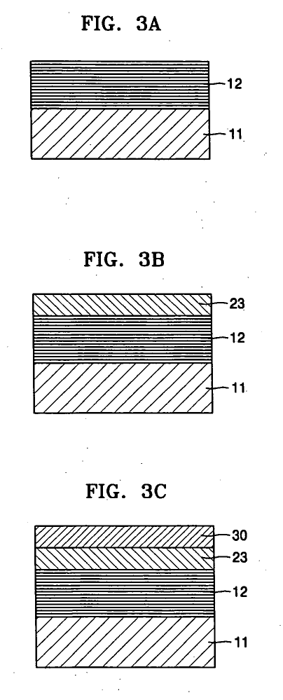

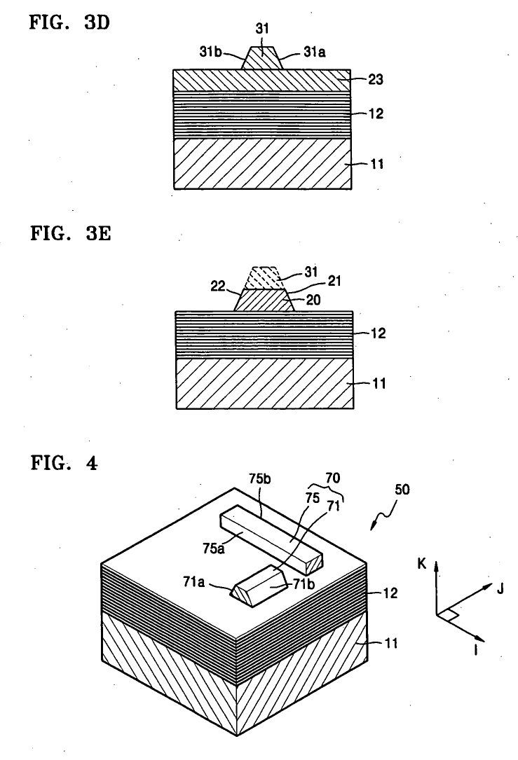

FIGS. 3A through 3E are sectional views illustrating a method of manufacturing a mask for EUVL according to an example embodiment of the present invention.

Referring to FIG. 3A, a material layer that can reflect EUV rays, for example, a Mo/Si multilayer, is deposited on a substrate 11 to form a reflection layer 12. RF magnetron sputtering or ion-beam sputtering may be used to form the reflection layer 12. In addition, conditions for sputtering may vary according to the apparatus used.

Referring to FIG. 3B, an absorption layer 23 is formed by depositing a material that can absorb EUV rays, for example TaN, on the reflection layer 12. When the absorption layer 23 is formed of a nitride, reactive sputtering may be used to form the absorption layer 23. Alternatively, when the absorption layer 23 is formed of other materials, DC sputtering may be used.

Referring to FIG. 3C, a resist layer 30 may be formed on the absorption layer 23.

Referring to FIG. 3D, the resist layer 30 may be exposed to energy, for example, an electron beam, to be patterned and developed, thus forming a resist pattern 31 with a given pattern. The resist pattern 31 may be used as a mask to form a desired pattern in the absorption layer 23. Side surfaces 31a and 31b of the resist pattern 31 may be formed to have angles of inclination substantially equal to angles of inclination of side surfaces 21 and 22 (see FIG. 3E) of the pattern which are to be formed in the absorption layer 23. For example, the angles of inclination of the side surfaces 31a and 31b of the resist pattern 31 may be formed to have inclination angles substantially equal to the angle of incidence of the EUV rays to be impinged. In addition, in an example embodiment a cross-section of the resist pattern 31 may have a trapezoidal shape.

Referring to FIG. 3E, the absorption layer 23 may be patterned to form an absorption pattern 20. The resist pattern 31 may be used as a mask while using, for example, an inductively coupled plasma (ICP) dry etching method. When the patterning is completed, the angles of inclination of the side surfaces 21 and 22 of the absorption pattern 20 are substantially equal to the angles of inclination of the side surfaces 31a and 31b of the resist pattern 31. Accordingly, the side surfaces 21 and 22 of the absorption pattern 20 adjacent to windows may be inclined with respect to the reflection layer 12. Further, in an example embodiment, the angles of inclination of the side surface 21 and 22 of the absorption pattern 20 may be substantially equal to angles of incidence of the EUV rays to be used.

After the absorption pattern 20 is formed, the resist pattern 31 may be removed.

FIG. 4 is a perspective view of a mask for EUVL according to another example embodiment of the present invention, wherein an absorption pattern 70 is partially illustrated. A mask for EUVL 50 according to an example embodiment may be the same as the mask for EUVL 10 which has been described with reference to FIGS. 2 through 3E, except that an absorption pattern 70 may further include side surfaces 75a and 75b perpendicular to a reflection layer 12.

Referring to FIG. 4, the absorption pattern 70 of the mask for EUVL 50 according to an example embodiment may have one or more side surfaces that are not perpendicular to the refection layer 12 and one or more side surfaces that are perpendicular to the refection layer 12.

In other example embodiments, the absorption pattern 70 may include a first absorption pattern 71 having side surfaces 71a and 71b that are not perpendicular to the reflective layer 12 and a second absorption pattern 75 having side surfaces 75a and 75b that are perpendicular to the reflection layer 12.

A first absorption pattern 71 may be formed in a direction perpendicular to an incident plane of EUV rays, that is, in a J-axis direction (shown in FIG. 4). A second absorption pattern 75 may be formed in a direction parallel to the incident plane of EUV rays, that is, in an I-axis direction. In an example embodiment, the incident plane of EUV rays may be made by EUV rays incident on the refection layer 12 and an incident surface, that is, a normal line perpendicular to the surface of the reflection layer 12. In the example of FIG. 4, the incident plane of EUV rays is parallel to an I-K plane.

In an example embodiment, two or more side surfaces 71a and 71b of the first absorption pattern 71 may be non-perpendicular with respect to the reflection layer 12. In addition, in an example embodiment the first absorption pattern 71 may have a trapezoidal-shaped cross-section. In an example embodiment, the angles of inclination of inclined side surfaces 71a and 71b of the first absorption pattern 71 may be substantially equal to the angle of incidence of the EUV rays incident on the reflection layer 12.

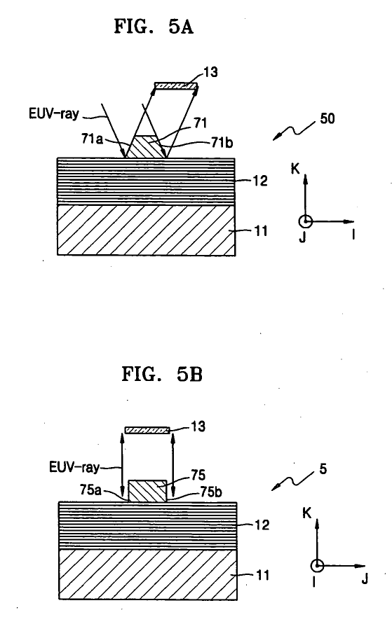

FIG. 5A is a schematic sectional view of the profile of a first absorption pattern 71 and FIG. 5B is a schematic sectional view of the profile of a second absorption pattern 75.

Referring to FIG. 5A, by forming one or more side surfaces 71a and 71b of the first absorption pattern 71 to have an inclination angle equal to the angle of incidence or reflection of the EUV rays, a pattern having a width substantially equal to a maximum width of the first absorption pattern 71 can be formed in the silicon wafer 13.

In example embodiments of the present invention, the second absorption pattern 75, arranged perpendicular to the first absorption pattern 71, may also have one or more inclined side surfaces.

In example embodiments of the present invention, the second absorption pattern 75, arranged perpendicular to the first absorption pattern 71, may have parallel side surfaces.

In example embodiments of the present invention, when the side surfaces 75a and 75b of the second absorption pattern 75 parallel to the incident plane of EUV rays are formed perpendicular to the reflection layer 12, a shadow effect may not occur. Therefore, an error in a line width of the pattern in the silicon wafer 13 may be reduced or minimized. Referring to FIG. 5B, because the side surfaces 75a and 75b of the second absorption pattern 75 are formed to be perpendicular to the reflection layer 12, a width of the pattern formed in the silicon wafer 13 is substantially equal to the width of the second absorption pattern 75.

Accordingly, when the first absorption pattern 71 perpendicular to the incident plane of EUV rays and the second absorption pattern 75 parallel to the incident plane of EUV rays are separately formed, a shadow effect can be reduced or prevented when EUV exposure is performed, and thus, the line width of the pattern can be more precisely realized on the silicon wafer 13.

A method of manufacturing a mask for EUVL according to another example embodiment of the present invention will now be described.

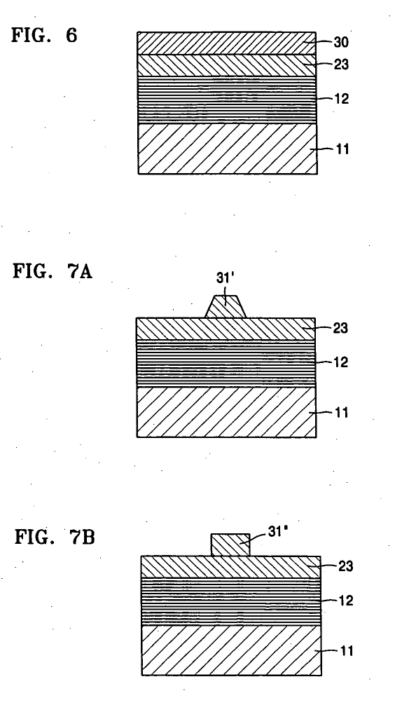

Referring to FIG. 6, a reflection layer 12, an absorption layer 23, and a resist layer 30 may be sequentially formed on a substrate 11. Because the respective layers illustrated in FIG. 6 are substantially the same as the respective layers illustrated in FIG. 3C, the same reference numeral are used on the corresponding layers in FIGS. 3C and 6.

Referring to FIGS. 7A and 7B, the resist layer 30 formed on the absorption layer 23 formed of a metal material may be patterning by electron beam writing and the pattern may be developed. As a result, resist patterns 31′ and 31″ having side surfaces whose angles of incidence are equal to angles of inclination of side surfaces of an absorption pattern that is to be formed, are formed.

FIG. 7A illustrates a first resist pattern 31′ having side surfaces whose angles of inclination are substantially equal to an angle of incidence of EUV rays. The first resist pattern 31′ may be used to form a first absorption pattern 71 having inclined side surfaces 71a and 71b. FIG. 7B illustrates a second resist pattern 31″ having side surfaces of which angles of inclination are 90°. The second resist pattern 31″ may be used to form a second absorption pattern 75 having side surfaces 75a and 75b whose angles of inclination are 90°.

In example embodiments, the formation angles of the first and second resist pattern 31′ and 31″ may be adjusted for different conditions.

In an example embodiment, the operation of electron beam writing may be performed in two stages. Electron beam writing may be performed to form the first resist pattern 31′, which is perpendicular to the incident plane of EUV rays and has one or more inclined side surfaces with angles of inclination equal to the angle of incidence of the EUV rays. Then, electron beam writing may be performed to form the second resist pattern 31″, which is parallel to the incident plane of EUV rays and has one or more side surfaces whose angles of inclination are 90°. In an example embodiment, the electron beam writing for formation of the first resist pattern 31′ may be performed after the electron beam writing for formation of the second resist pattern 31″.

When the resist layer 30 is developed after electron beam writing is performed in two stages, the first and second resist patterns 31′ and 31″ may be obtained as illustrated in FIGS. 7A and 7B. In order to form the first and second resist patterns 31′ and 31″ as described above, the resist layer 30 may patterned in at least two stages.

Like the resist pattern 31 according to example embodiments of the present invention described with reference to FIGS. 2 through 3E, the first resist pattern 31′ may have side surfaces with angles of inclination equal to the angle of incidence of the EUV rays. By using the first resist pattern 31′, the first absorption pattern 71 having side surfaces 71a and 71b with angles of inclination equal to the angle of incidence of EUV rays can be formed. In addition, the first resist pattern 31′ may be formed to have a trapezoidal-shaped cross-section, and thus, the first absorption pattern 71 may be formed to have a trapezoidal-shaped cross-section.

After the first and second resist patterns 31′ and 31″ are formed, the absorption layer 23 may be etched by, for example, dry etching using the first and second resist patterns 31′ and 31″ as a mask for etching, thus forming the absorption pattern 70 including the first and second absorption patterns 71 and 75 having inclination angles being equal to the angles of inclination of the side surfaces of the first and second resist patterns 31′ and 31″.

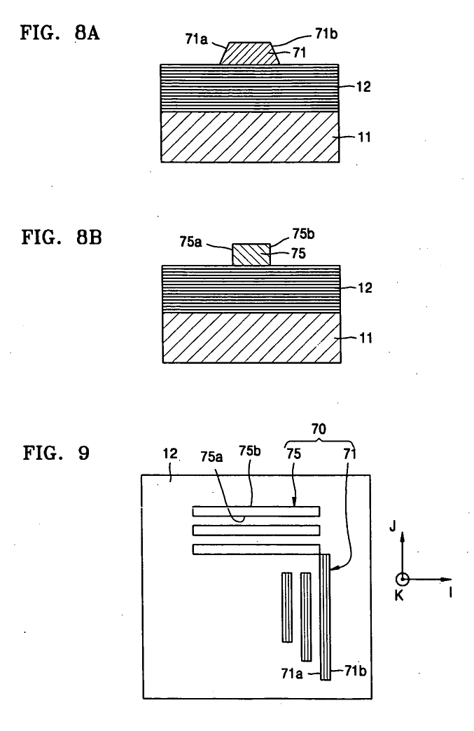

FIG. 8A illustrates a section of the first absorption pattern 71, FIG. 8B illustrates a section of the second absorption pattern 75, and FIG. 9 illustrates an example of the absorption pattern 70 including the first and second absorption patterns 71 and 75.

One or more side surfaces 71a and 71b of the first absorption pattern 71 may be formed to have angles of inclination substantially equal to the angle of incidence of the EUV rays. One or more side surfaces 75a and 75b of the second absorption pattern 75 may be formed to be perpendicular to the refection layer 12.

As described above, in order to form the absorption pattern 70 of the mask for EUVL 50 according to an example embodiment of the present invention, a resist may be formed on the absorption layer 23 of a metal material to form the resist layer 30, and, a desired pattern may be formed in the resist layer 30 by electron beam writing. In an example embodiment, the first resist pattern 31′ corresponding to the first absorption pattern 71 having one or more inclined side surfaces 71a and 71b and the second resist pattern 31″ corresponding to the second absorption pattern 75 having one or more vertical side surfaces 75a and 75b may be formed under different conditions such that formation angles of the first and second resist patterns 31′ and 31″ may be adjusted.

For example, electron beam writing to obtain the first resist pattern 31′ may be performed under conditions including fixing an intensity of a writing field or a dose factor of an electron beam, an opening size of 20 μm, a voltage of 15 KeV, and/or a step size of 15 nm. Electron beam writing to obtain the second resist pattern 31″ may be performed under conditions including an opening size of 15 μm, a voltage of 12 KeV, and/or a step size of 20 nm.

When electron beam writing is performed and the resist layer 30 is developed, a resist pattern including the first resist pattern 31′ having a trapezoidal-shaped cross-section and angles of inclination of, for example, 84°, and the second resist pattern 31″ having a rectangle-shaped cross-section and angles of inclination of, for example, 90° may be obtained.

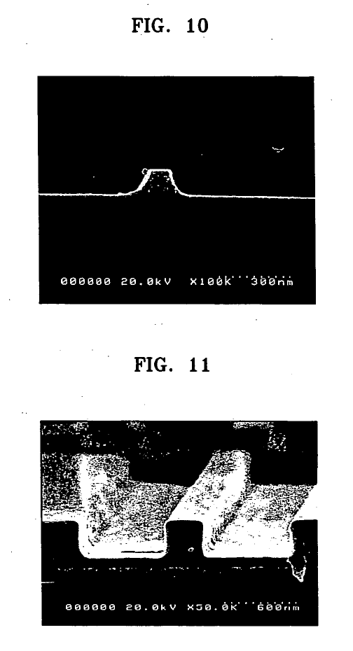

When dry etching is performed using a Cl-based gas and using the resist patterns formed described above as a mask, the absorption pattern 70 including the first absorption pattern 71 having one or more side surfaces 71a and 71b inclined according to the inclination of the resist pattern and the second absorption pattern 75 having one or more vertical side surfaces 75a and 75b may be obtained. FIG. 10 illustrates a section of the absorption pattern 70 having one or more inclined side surfaces formed under the above-described conditions, that is, a section of the first absorption pattern 71. FIG. 11 illustrates a section of the absorption pattern 70 having one or more vertical side surfaces formed under the above-described conditions, that is, a section of the second absorption pattern 75.

In a mask for EUVL according to example embodiments the present invention, at least a portion of one or more side surfaces of an absorption pattern adjacent to a window may be inclined with respect to a reflection layer such that a shape designed in the absorption pattern may be more precisely realized into a wafer, for example, using a photolithography technique.

In addition, an absorption pattern may be formed to have mixed side surfaces of one or more inclined side surfaces and one or more vertical side surfaces so that an absorption pattern perpendicular to an incident plane of EUV rays has one or more side surfaces inclined with respect to the reflection layer, and an absorption pattern parallel to the incident plane of EUV rays has one or more side surfaces perpendicular to the reflection layer. By mixing side surfaces of one or more inclined side surfaces and one or more vertical side surfaces, when EUV exposure is performed, a shadow effect can be reduced or prevented and/or an error in a line width of the pattern can be reduced or minimized. Example embodiments of the present invention are described in conjunction with EUVL radiation. In example embodiments, EUVL radiation may be defined as radiation on the order of 1-2 to 30 petahertz (PHz), have a wavelength on the order of 10-100 nm, and/or have an energy of the order 12.4-124 eV. In other example embodiments, soft X-ray radiation may be used. In example embodiments, soft X-ray radiation may be defined as radiation on the order of 30 petahertz (PHz) to 3 exahertz (EHz), have a wavelength on the order of 100 pm to 10 nm, and/or have an energy of the order 124 eV to 12.4 keV. In still other example embodiments, any type of electromagnetic radiation may be used.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A mask for lithography comprising:
a substrate;
a reflection layer formed of a material capable of reflecting electromagnetic radiation on the substrate; and
an absorption pattern having an absorption region with respect to electromagnetic rays and a window through which the electromagnetic rays pass, the absorption pattern including at least one side surface that is adjacent to the window and is inclined with respect to the reflection layer.

2. The mask of claim 1, wherein the absorption pattern further includes at least one side surface that is perpendicular to the reflection layer such that the absorption pattern has at least one inclined surface and at least one vertical side surface.

3. The mask of claim 2, wherein the absorption pattern comprises a first absorption pattern having the at least one inclined surface and a second absorption pattern having the at least one vertical side surface.

4. The mask of claim 3, wherein at least two side surfaces of the first absorption pattern are inclined with respect to the reflection layer.

5. The mask of claim 3, wherein the cross-section of the first absorption pattern is trapezoid-shaped.

6. The mask of claim 3, wherein the first absorption pattern is formed in a direction perpendicular to an incident plane of the electromagnetic rays and the second absorption pattern is formed in a direction parallel to the incident plane of the electromagnetic rays.

7. The mask of claim 2, wherein the at least one inclined side surface of the absorption pattern has an angle of inclination equal to the angle of incidence of the electromagnetic rays incident on the reflection layer.

8. The mask of claim 1, wherein the at least one inclined side surface of the absorption pattern has an angle of inclination equal to the angle of incidence of the electromagnetic rays incident on the reflection layer.

9. The mask of claim 1, wherein at least two side surfaces of the absorption pattern are inclined with respect to the reflection layer.

10. The mask of claim 1, wherein the cross-section of the absorption pattern having an inclined side surface is trapezoid-shaped.

11. The mask of claim 1, wherein the absorption pattern is formed of a metal-containing material.

12. The mask of claim 11, wherein the absorption pattern is formed of an element selected from the group consisting of TaN, Ta, Cr, TiN, Ti, Al—Cu, NiSi, TaSiN, and Al.

13. The mask of claim 1, wherein the reflection layer is composed of alternatively deposited first material layers and second material layers.

14. The mask of claim 13, wherein the first material layers are formed of an element selected from the group consisting of Mo, Sc, Ti, V, Cr, Fe, Ni, Co, Zr, Nb, Tc, Ru, Rh, Hf, Ta, W, Re, Os, Ir, Pt, Cu, Pd, Ag, and Au.

15. The mask of claim 13, wherein the second material layers are formed of a material selected from the group consisting of silicon, silicon carbonate, silicon nitride, silicon oxide, boron nitride, beryllium nitride, beryllium oxide, aluminum nitride, and aluminum oxide.

16. The mask of claim 1, wherein the electromagnetic radiation is extreme ultra violet (EV) radiation.

17. A method of manufacturing a mask for lithography, the method comprising:
forming a reflection layer formed of a material capable of reflecting electromagnetic rays on a substrate;
forming an absorption layer formed of a material capable of absorbing electromagnetic rays on the refection layer; and
patterning the absorption layer to form an absorption pattern with at least one side surface adjacent to a window that include at least one inclined side surface with respect to the reflection layer.

18. The method of claim 17, wherein forming the absorbing pattern in the absorbing layer includes:
forming a resist layer on the absorption layer;
patterning the resist layer to form a resist pattern; and
patterning the absorption layer using the resist pattern as a mask to form the absorption pattern having the at least one inclined side surface.

19. The method of claim 18, wherein forming the resist pattern in the resist pattern in the resist layer includes:
forming a resist pattern having at least one side surface inclined equal to the angle of incidence of electromagnetic rays and
forming the inclined absorption pattern in the absorption layer includes forming an absorption pattern having at least one side surface inclined at an angle equal to an angle of inclination of at least one side surface of the resist pattern.

20. The method of claim 19, wherein at least two side surfaces of the resist pattern are formed to be inclined equal to the angle of incidence of the electromagnetic rays.

21. The method of claim 19, wherein at least two side surfaces of the absorption pattern having inclined side surfaces have angles of inclination equal to the angle of inclination of at least one side surface of the resist pattern.

22. The method of claim 19, wherein the cross-section of the resist pattern is trapezoid-shaped.

23. The method of claim 17, wherein forming the absorption pattern includes patterning the absorption layer further to have at least one side surface vertical to the reflection layer to form an absorption layer having mixed side surfaces including at least one inclined side surface and at least one vertical side surface.

24. The method of claim 23, wherein the absorption pattern includes a first absorption pattern having the at least one inclined side surface and a second absorption pattern having the at least one vertical side surface.

25. The method of claim 24, wherein at least two side surfaces of the first absorption pattern are inclined with respect to the reflection layer.

26. The method of claim 24, wherein the cross-section of the first absorption pattern is trapezoid-shaped.

27. The method of claim 24, wherein the first absorption pattern is formed in a direction perpendicular to an incident plane of electromagnetic rays and the second absorption pattern is formed in a direction parallel to the incident plane of electromagnetic rays.

28. The method of claim 23, wherein forming the absorption pattern in the absorption layer includes:
forming a resist layer on the absorption layer;
forming a resist pattern having at least one side surface with an angle of inclination equal to the angle of inclination of at least one side surface of the absorption pattern to be formed, on the resist layer; and
forming the absorption pattern in the absorption layer using the resist pattern as a mask such that an angle of inclination of the at least one side surface of the absorption pattern with respect to the reflection layer is equal to the angle of inclination of the at least one side surface of the resist pattern with respect to the reflection layer.

29. The method of claim 28, wherein forming the resist pattern includes:
patterning of the resist layer in at least two stages including:
forming a first resist pattern having at least one side surface with an angle of inclination equal to an angle of incidence of electromagnetic rays to be used to form the absorption pattern having at least one inclined side surface; and
forming a second resist pattern having at least one side surface having an angle of inclination of 90° to be used to form the absorption pattern having at least one vertical side surface, and
forming the absorption pattern includes:
forming the portion of the absorption pattern with at least one inclined side surfaces using the first resist pattern and the portion of the absorption pattern with the at least one vertical side surface using the second resist pattern.

30. The method of claim 29, wherein at least two side surfaces of the first resist pattern are formed to be inclined equal to the angle of incidence of electromagnetic rays.

31. The method of claim 29, wherein the cross-section of the first resist pattern is trapezoid-shaped.

32. The method of claim 17, wherein the absorption pattern is formed such that at least one side surface of the absorption pattern adjacent to a window has an angle of inclination equal to the angle of incidence of electromagnetic rays.

33. The method of claim 16, wherein the absorption pattern is formed to have a trapezoid-shaped cross-section.

34. The method of claim 17, wherein the absorption pattern is formed of a metal-containing material.

35. The method of claim 34, wherein the absorption pattern is formed of a material selected from the group consisting of TaN, Ta, Cr, TiN, Ti, Al—Cu, NiSi, TaSiN, and Al.

36. The method of claim 17, wherein the forming of the reflection layer on the substrate comprises: alternately depositing first material layers and second material layers.

37. The method of claim 36, wherein the first material layers are formed of an element selected from the group consisting of Mo, Sc, Ti, V, Cr, Fe, Ni, Co, Zr, Nb, Tc, Ru, Rh, Hf, Ta, W, Re, Os, Ir, Pt, Cu, Pd, Ag, and Au.

38. The method of claim 36, wherein the second material layers are formed of a material selected from the group consisting of silicon, silicon carbonate, silicon nitride, silicon oxide, boron nitride, beryllium nitride, beryllium oxide, aluminum nitride, and aluminum oxide.

39. The method of claim 17, wherein the electromagnetic radiation is extreme ultra violet (EUV) radiation.
